(19) United States
(12) Patent Application Publication
(10) Pub. No.: US 2025/0089345 A1
(43) Pub. Date: Mar. 13, 2025

(54) MATERIALS AND METHODS FOR COMPLEMENTARY FIELD-EFFECT TRANSISTORS HAVING MIDDLE DIELECTRIC ISOLATION LAYER

(71) Applicant: Applied Materials, Inc., Santa Clara, CA (US)

(72) Inventors: San-Kuei Lin, Los Gatos, CA (US); Pradeep K. Subrahmanyan, Los Gatos, CA (US)

(73) Assignee: Applied Materials, Inc., Santa Clara, CA (US)

(21) Appl. No.: 18/824,088

(22) Filed: Sep. 4, 2024

Related U.S. Application Data
(60) Provisional application No. 63/537,056, filed on Sep. 7, 2023.
(60) Provisional application No. 63/537,005, filed on Sep. 7, 2023.

(51) Int. Cl. H01L 21/822; H01L 21/8238; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 84/0167; H10D 84/856; H10D 88/01

(57) ABSTRACT

Embodiments of the disclosure advantageously provide semiconductor devices CFET in particular, and methods of manufacturing such devices having a fully strained superlattice structure with channel layers that are substantially free of defects and release layers that are protected from material loss during removal of a middle sacrificial layer. The CFET described herein comprise a vertically stacked superlattice structure on a substrate, the vertically stacked superlattice structure comprising: a first hGAA structure on the substrate; a middle sacrificial layer on a top surface of the first hGAA structure, the middle sacrificial layer comprising silicon germanium (SiGe); and a second hGAA structure on a top surface of the sacrificial layer. Each of the first hGAA and the second hGAA comprise alternating layers of nanosheet channel layer that comprise silicon (Si) and nanosheet release layer that comprise silicon germanium (SiGe). The middle sacrificial layer and the nanosheet release layers can comprise silicon germanium (SiGe) having the same or substantially the same geranium content.

### CROSS-REFERENCE TO RELATED APPLICATIONS

This application claims priority to U.S. Provisional Application No. 63/537,056, filed Sep. 7, 2023, and to United States Provisional Application No. 63,537,005, filed on Sep. 7, 2023, the entire disclosures of which are hereby incorporated by reference herein.

### TECHNICAL FIELD

Embodiments of the present disclosure pertain to the field of electronic device manufacturing, and in particular, to transistors. More particularly, embodiments of the disclosure are directed to complementary field-effect transistors (CFETs), and methods of forming the same.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a gate all around (GAA) structure. The GAA device structure includes several lattice matched channels suspended in a stacked configuration and connected by source/drain regions. The GAA structure provides good electrostatic control and can find broad adoption in complementary metal oxide semiconductor (CMOS) wafer manufacturing.

One example of gate-all-around (GAA) technology is a complementary field effect transistor (CFET), where nFET and pFET nanowires/nanosheets are vertically stacked on top of each other. CFET transistors have increased on-chip device density and reduced area consumption when compared to GAA transistors. When stacking nFET and pFET in a monolithic manner, the n and p superlattice are deposited sequentially with a middle sacrificial layer that is selectively removed and replaced with a middle dielectric isolation (MDI) layer during processing. The MDI layer serves to electrically isolate the lower-level GAA from the upper-level GAA.

Each n or p superlattice of a CFET includes alternating layers of channel layers and release layers. The release layers typically comprise silicon germanium (SiGe) with a low concentration of germanium (Ge). For etch contrast between the middle sacrificial layer verses the channel layers and the release layers, the middle sacrificial layer comprises SiGe with a high concentration of Ge.

However, when providing a structure with such a high concentration of Ge in the middle sacrificial layer, the superlattice relaxes, and strain and mobility reduce, resulting in poor transistor performance due to reduced drive current. Further, while providing the middle sacrificial layer with a relatively high concentration of Ge provides etch contrast and selective removal of the middle sacrificial layer, an undesirable loss of SiGe within the release layers occurs, resulting in the release layers becoming rough and damaged. Additionally, the Si channel layers can become rounded during removal of the middle sacrificial layer. As a result, the superlattice is provided with a non-uniform profile, which negatively impacts device performance and leads to device variation.

Accordingly, there is a need for semiconductor devices, CFET in particular, and methods of manufacturing such devices having a fully strained superlattice structure with channel layers that are uniform and free or substantially free of defects. There is a further need for semiconductor devices, CFET in particular, and methods of manufacturing such devices with channel and release layers that are protected from damage and loss during removal of the middle sacrificial layer.

### SUMMARY

An aspect of the disclosure is directed to a method of forming a semiconductor device, the method comprising forming a vertically stacked superlattice structure on a substrate by forming a first horizontal gate-all-around (hGAA) structure on the substrate, the first hGAA structure comprising alternating layers of nanosheet channel layer and nanosheet release layer; forming a middle sacrificial layer on a top surface of the first hGAA structure; forming a second horizontal gate-all-around (hGAA) structure on a top surface of the sacrificial layer, the second hGAA structure comprising alternating layers of nanosheet channel layer and nanosheet release layer; depositing an encapsulating material to fill one or more trenches in the vertically stacked superlattice structure and surround the vertically stacked superlattice structure; removing a portion of the encapsulating material to expose the second hGAA structure; depositing a protection liner on the second hGAA structure; removing a portion of the encapsulating material to expose the middle sacrificial layer; and removing the middle sacrificial layer, wherein the first hGAA structure is covered by the encapsulating material and the second hGAA structure is covered by the protective liner during removal of the middle sacrificial layer.

Another aspect of the disclosure is directed to a method of forming a semiconductor device, the method comprising forming a vertically stacked superlattice structure on a substrate by forming a first horizontal gate-all-around (hGAA) structure on the substrate, the first hGAA structure comprising alternating layers of nanosheet channel layer and nanosheet release layer; forming a middle sacrificial layer on a top surface of the first hGAA structure; forming a second horizontal gate-all-around (hGAA) structure on a top surface of the sacrificial layer, the second hGAA structure comprising alternating layers of nanosheet channel layer and nanosheet release layer; and etching the middle sacrificial layer, wherein the alternating layers of nanosheet release layer in the first hGAA structure and the second hGAA structure and the middle sacrificial layer comprise the same material, wherein the second hGAA structure is shielded by a protective liner while etching the middle sacrificial layer and the first hGAA structure is shielded by an encapsulating material while etching the middle sacrificial layer, and wherein etching the middle sacrificial layer results in no loss of material forming the alternating layers of nanosheet release layer in the first hGAA structure and the second hGAA structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of manufacturing a complementary field effect transistor (CFET) according to one or more embodiments;

FIG. 2 illustrates a schematic cross-sectional view of a vertically stacked superlattice structure on a semiconductor substrate according to one or more embodiments;

FIGS. 3A to 3E illustrate a sequence of process operations for manufacturing a CFET with a middle dielectric isolation (MDI) layer according to a prior technique;

FIG. 4 illustrates a bi-cross-sectional view of a vertically stacked superlattice structure according to one or more embodiments after post gate spacer deposition;

FIG. 5A illustrates a desired vertically stacked superlattice structure after selective removal of a middle sacrificial layer;

FIG. 5B illustrates a vertically stacked superlattice structure after selective removal of a middle sacrificial layer according to a prior technique;

FIG. 6 illustrates a bi-cross-sectional view of a vertically stacked superlattice structure after post gate spacer deposition, according to one or more embodiments;

FIG. 7 illustrates a bi-cross-sectional view of a vertically stacked superlattice structure after source/drain global etching, according to one or more embodiments;

FIG. 8 illustrates a bi-cross-sectional view of a vertically stacked superlattice structure after a carbon spin-on or CVD gap fill and planarization process, according to one or more embodiments;

FIG. 9 illustrates a bi-cross-sectional view of a vertically stacked superlattice structure after a carbon etch back process to expose an upper horizontal gate-all-around (hGAA) structure, according to one or more embodiments;

FIG. 10 illustrates a bi-cross-sectional view of a vertically stacked superlattice structure after deposition of a protective liner which covers the tops and side surfaces of gates, side surfaces of the upper hGAA structure, and upper surfaces of the carbon spin-on or CVD gap fill material, according to one or more embodiments;

FIG. 11 illustrates a bi-cross-sectional view of a vertically stacked superlattice structure after etching the protection liner to expose the upper surfaces of the carbon spin-on or CVD gap fill material, according to one or more embodiments;

FIG. 12 illustrates a bi-cross-sectional view of a vertically stacked superlattice structure after a carbon pull back process to expose the middle sacrificial layer, according to one or more embodiments;

FIG. 13 illustrates a bi-cross-sectional view of a vertically stacked superlattice structure after removal of the middle sacrificial layer, according to one or more embodiments;

FIG. 14 illustrates a bi-cross-sectional view of a vertically stacked superlattice structure after deposition of a middle dielectric isolation (MDI) layer material according to one or more embodiments;

FIG. 15 illustrates a bi-cross-sectional view of a vertically stacked superlattice structure after removing the MDI layer material from the tops and side surfaces of gates, side surfaces of the upper hGAA structure and trenches in the upper hGAA structure, according to one or more embodiments;

FIG. 16 illustrates a bi-cross-sectional view of a vertically stacked superlattice structure after removing a remainder of carbon from the carbon spin-on or CVD gap fill, to expose the lower horizontal gate-all-around (hGAA) structure, and an MDI layer material densification process to form the MDI layer, according to one or more embodiments;

FIG. 17 illustrates a bi-cross-sectional view of a vertically stacked superlattice structure after removing the protective liner, according to one or more embodiments;

FIG. 18 illustrates a bi-cross-sectional view of a CFET having a top stack isolated from a bottom stack with an MDI layer fabricated according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15%, or less, of the numerical value. For example, a value differing by +14%, +13%, +12%, +11%, +10%, +9%, +8%, +7%, +6%, +5%, +4%, +3%, +2%, or +1%, would satisfy the definition of about.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon. A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Epitaxy” is a process by which a deposited film is forced into a high degree of crystallographic alignment with the substrate. Epitaxial growth is broadly defined as the condensation of gas precursors to form a film on a substrate. Liquid precursors may also be used. Vapor precursors may be obtained by chemical vapor deposition (CVD) and laser ablation. Several epitaxy techniques are now available, such as molecular beam epitaxy (MBE), epitaxial CVD, or atomic layer epitaxy (ALE).

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Field effect transistors are voltage-controlled devices where its current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated IS and current entering the channel at the drain (D) is designated ID. Drain-to-source voltage is designated VDS. By applying voltage to gate (G), the current entering the channel at the drain (i.e., ID) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both are of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p-type substrate region. If the MOSFET is a p-channel or pMOS FET, then the source and drain are p+ regions and the body is a n-type substrate region. The source is so named because it is the source of the charge carriers (electrons for n-channel, holes for p-channel) that flow through the channel; similarly, the drain is where the charge carriers leave the channel.

A nMOS FET, is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. sLogic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors.

As used herein, the term “nanowire” refers to a nanostructure, with a diameter on the order of a nanometer (10-9 meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

As used herein “material loss” in layers, particularly “material loss” in nanosheet release layers and/or nanosheet channel layers refers to a loss or removal of a portion of the material forming these layers. In particular, a “material loss” in the nanosheet release layers and/or the nanosheet release layers is described herein in connection with a loss or removal of a portion of the material forming these layers during removal of a middle sacrificial layer. For example, in an embodiment with a middle sacrificial layer formed of SiGe, nanosheet release layers formed of SiGe (with the same or different concentration of Ge), and nanosheet channel layers formed of Si, a removal process (such as etching or another suitable removal process) carried out for removal of the middle sacrificial layer results in an unintentional loss or removal of a portion of the SiGe forming the nanosheet release layers and/or a loss or removal of a portion of the Si forming the nanosheet channel layers.

Generally, in order to remove a middle sacrificial layer within a CFET superlattice by an etch process without etching nanosheet release layers, a three-color selectivity of >10:1 is required. Within typical patterned wafers, selectivity is very high for SiGe versus Si (e.g., nanosheet channel layers formed of Si versus a middle sacrificial layer and nanosheet release layers formed of SiGe), meeting the >10:1 requirement. Selectivity, however, is much lower for SiGe with high germanium content (i.e., above 30% on an atomic basis) versus SiGe with low germanium content (i.e., 15-20% on an atomic basis), and does not satisfy the >10:1 requirement. Thus, monolithic CFETs have been fabricated by relying upon a relatively high germanium content within the middle sacrificial layer relative to the germanium content in the nanosheet release layers.

Without intending to be bound by any particular theory of operation, it is believed that relying upon a selective etch process based on a relatively high germanium content within a middle sacrificial layer relative to the germanium content in nanosheet release layers of a vertically stacked superlattice structure causes defects because some material loss also occurs within the nanosheet release layers. Without intending to be bound by any particular theory of operation, it is further believed that the selective etch process can cause a loss of material forming the nanosheet channel layers, resulting in nanosheet channel layers having a rounded profile after etching the middle sacrificial layer. Embodiments of the present disclosure advantageously provide a vertically stacked superlattice structure in which a loss of material forming the nanosheet release layers and nanosheet channel layers is minimized or prevented while removing the middle sacrificial layer. In some embodiments, a loss of material forming the nanosheet release layers and nanosheet channel layers is minimized or prevented by etching an exposed middle sacrificial layer while protecting both the upper hGAA structure and the lower hGAA structure, for example, by coating the upper hGAA structure with a protective liner and surrounding the lower hGAA structure with a protective gap fill material. In some embodiments, selective etching of the middle sacrificial layer can be accomplished without relying upon etch selectivity of a material forming the middle sacrificial layer relative to a material forming the nanosheet release layers.

According to one or more embodiments, any materials can be used in forming the middle sacrificial layer and the nanosheet release layers, and selective etching of the middle sacrificial layer can be carried out while minimizing or preventing etching of the nanosheet release layers. According to one or more embodiments, a material forming the middle sacrificial layer can have an etch selectivity higher than that of the material forming the nanosheet release layers. According to one or more embodiments, a material forming the middle sacrificial layer can have an etch selectivity that is the same or substantially the same as the material forming the nanosheet release layers. According to one or more embodiments, the same or substantially the same material can be used in forming the middle sacrificial layer and the nanosheet release layers. According to one or more embodiments, the nanosheet channel layers comprise Si, and the middle sacrificial layer and the nanosheet release layers independently comprise SiGe. According to one or more embodiments, stacked layers of alternating nanosheet channel layers comprising Si and nanosheet release layers comprising SiGe, with a middle sacrificial layer comprising SiGe, are capable of forming vertically stacked superlattice structures that are strained and free of crystalline lattice defects. According to one or more embodiments, the material forming the middle sacrificial layer is the same as the material forming the nanosheet release layers, and fabrication of a vertical superlattice structure is simplified because fewer material compositions are needed in forming the various layers. Further, without being bound by theory, it is believed that using the same material composition (e.g., the same SiGe material) to form the middle sacrificial layer and the nanosheet release layers allows for not only a more simplified fabrication process, but also reduces potential defects that can occur during the fabrication process by using different materials.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

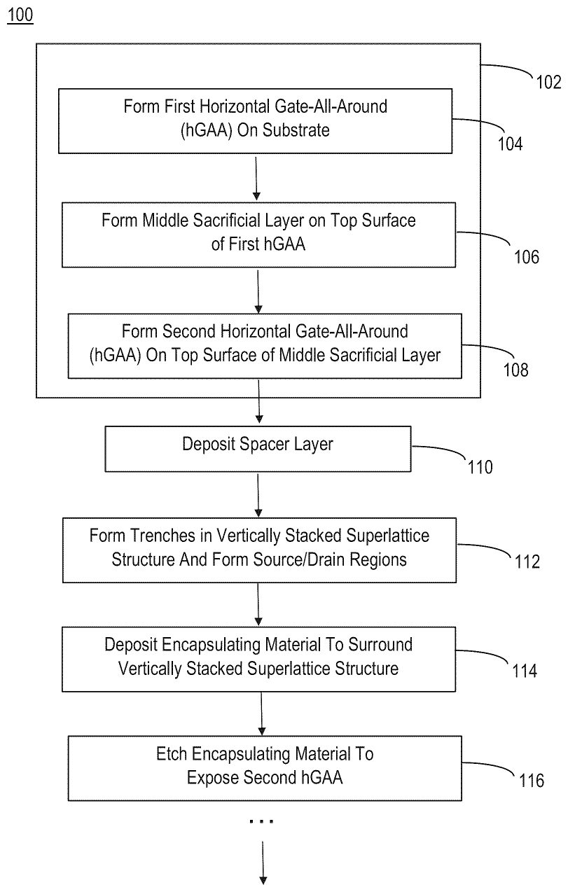

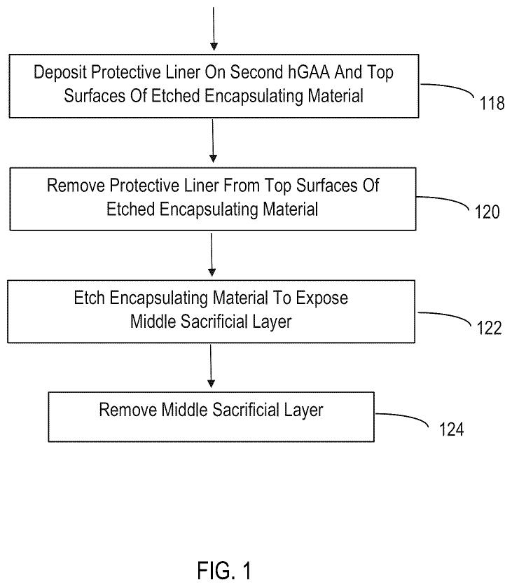

FIG. 1 depicts a process flow diagram of a method 100 of manufacturing a complementary field effect transistor (CFET) in accordance with one or more embodiments of the present disclosure. The method 100 comprises, at operation 102, forming a vertically stacked superlattice structure on a substrate. In one or more embodiments, the superlattice is strained and free of crystalline lattice defects. The vertically stacked superlattice structure is formed on the substrate by disposing a first or lower horizontal gate-all-around (hGAA) structure on the substrate, at operation 104. The first or lower hGAA is formed of alternating layers of nanosheet channel layers and nanosheet release layers. At operation 106, a middle sacrificial layer is formed on a top surface of the first or lower hGAA structure. At operation 108, a second or upper horizontal gate-all-around (hGAA) structure is formed on a top surface of the sacrificial layer. The second hGAA is formed of alternating layers of nanosheet channel layers and nanosheet release layers. After forming a gate structure on a top surface of the second hGAA, a spacer layer is deposited on an outer surface of the gate structure and a top surface of the hGAA not covered by the gate structure at operation 110. At operation 112, a series of trenches are etched in the vertically stacked superlattice structure and source/drain regions are formed. At operation 114, a spin-on, CVD carbon gap-fill, or other suitable process is performed to surround the entire vertical superlattice structure with an encapsulating material, from the top surface of the substrate to the tops of the gate structure, followed by planarization. At operation 116, the encapsulating material is etched to expose the gate structure and the second hGAA. At operation 118, a protective liner is deposited on the gate structure, the second hGAA, and exposed top surfaces of the etched encapsulating material. At operation 120, the protective liner is removed from the top surfaces of the etched encapsulating material. At operation 122, the method 100 includes etching the encapsulating material to expose the middle sacrificial layer. At operation 124, the middle sacrificial layer is removed so that a middle isolation layer may be formed during subsequent processing.

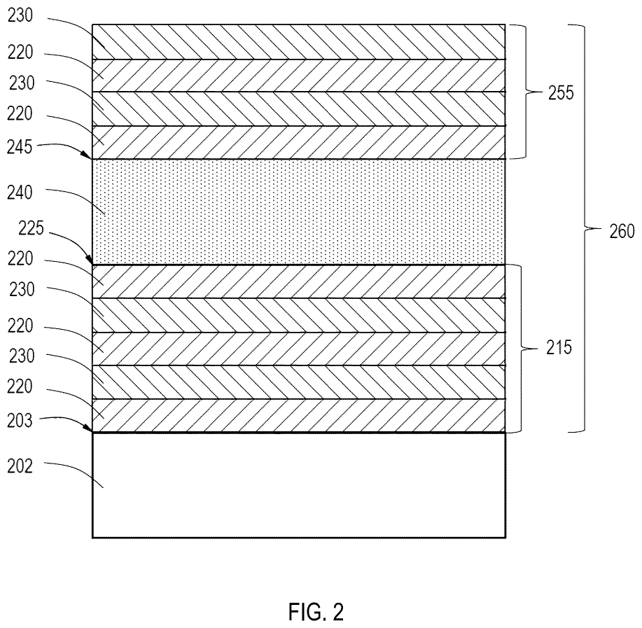

FIG. 2 shows a simplified view of a CFET device 200, which includes a substrate 210 having a top surface 212. The substrate 210 can be any suitable substrate material known to the skilled artisan. In one or more embodiments, the substrate 210 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 210 comprises one or more of silicon (Si), germanium (Ge), gallium (Ga), arsenic (As), indium (In), phosphorus (P), or selenium (Se). Although a few examples of materials from which the substrate 210 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In one or more embodiments, the substrate 210 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more embodiments, the vertically stacked superlattice structure 260 comprises one or more horizontal gate-all-around (hGAA) structures on the substrate 210. In some embodiments, the vertically stacked superlattice structure 260 comprises a first or lower horizontal gate-all-around (hGAA) structure 215 on a top surface 212 of the substrate 210. In some embodiments, the vertically stacked superlattice structure 260 comprises a second or upper horizontal gate-all-around (hGAA) structure 255. Without intending to be bound by any particular theory of operation, the first or lower hGAA 215 and the second or upper hGAA 255 may independently comprise the same structure having the same layers. According to one or more embodiments, the vertically stacked superlattice structure 260 comprises the first hGAA structure 215 on the top surface 212 of the substrate 210, a middle sacrificial layer 240 on a top surface 225 of the first hGAA structure 215, and the second hGAA structure 255 on a top surface 245 of the middle sacrificial layer 240.

In some embodiments, each of the first hGAA 215 and the second hGAA 255 comprise alternating layers of nanosheet channel layer 230 and nanosheet release layer 220. In some embodiments, the plurality of nanosheet release layers 220 and the plurality of nanosheet channel layers 230 can comprise any number of lattice matched material pairs suitable for forming the vertically stacked superlattice structure 260. In some embodiments, each of the first hGAA 215 and the second hGAA 255 have in a range of from 1 to 5 pairs of alternating layers of nanosheet channel layer 230 and nanosheet release layer 220.

The nanosheet release layers 220 may have any suitable thickness. In one or more embodiments, each nanosheet release layer 220 has a thickness in a range of from about 5 nm to about 15 nm. The nanosheet channel layers 230 may have any suitable thickness. In one or more embodiments, each nanosheet channel layer 230 has a thickness in a range of from about 4 nm to about 15 nm.

In some embodiments, each of the nanosheet channel layers 230 independently comprises silicon (Si). In some embodiments, each of the nanosheet release layers 220 independently comprises silicon germanium (SiGe). In one or more embodiments, the nanosheet release layers 220 comprises silicon germanium (SiGe) having a germanium content in a range of from greater than 0% to about 50% on an atomic basic. In specific embodiments, the nanosheet release layers 220 comprise silicon germanium (SiGe) having a germanium content in a range of from about 10% to about 40% on an atomic basis, including 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34% 35%, 36%, 37%, 38%, 39%, and 40% on an atomic basis.

In one or more embodiments, a sacrificial layer 240 is formed between the first or lower hGAA 215 and the second or upper hGAA 255. In one or more embodiments, the middle sacrificial layer 240 is selectively removed and replaced with a middle dielectric isolation (MDI) layer 340 during later processing. The middle dielectric isolation (MDI) layer 340 serves to electrically isolate the source/drain regions of the lower hGAA 215 from the source/drain regions of the upper hGAA 255. In one or more embodiments, the middle sacrificial layer 240 comprises silicon germanium (SiGe) having a germanium content of from greater than 0% to about 65% on an atomic basic. In specific embodiments, the middle sacrificial layer 240 comprise silicon germanium (SiGe) having a germanium content in a range of from about 10% to about 65% on an atomic basis, including 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34% 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, and 65% on an atomic basis.

According to one or more embodiments, the middle sacrificial layer 240 is fabricated of silicon germanium (SiGe) having a germanium content that is relatively higher than a germanium content in the nanosheet release layers 220. According to one or more embodiments, the nanosheet release layers 220 and the middle sacrificial layer 240 each individually comprise silicon germanium (SiGe) having substantially the same germanium content. By “substantially the same” content, it is meant that the germanium content in the nanosheet release layers 220 is within about +1% to 5% the germanium content in the middle sacrificial layer 240, on an atomic basis. According to one or more embodiments, the nanosheet release layers 220 and the middle sacrificial layer 240 each individually comprise silicon germanium (SiGe) having the same germanium content.

In one or more embodiments, the sacrificial layer 240 may have any suitable thickness. In some embodiments, the sacrificial layer 240 has a thickness in a range of from about 15 nm to about 90 nm, including a range of from about 15 nm to about 80, a range of from about 20 nm to about 75 nm, a range of from about 15 nm to about 60 nm, a range of from about 15 nm to about 50 nm, a range of from about 15 nm to about 75 nm, and a range of from about 20 nm to about 50 nm.

As recognized by one of skill in the art, during subsequent processing, the middle sacrificial layer 240 may be removed and replaced with a middle dielectric isolation (MDI) layer 340. Selectively removing the middle sacrificial layer 240 may be performed by any suitable means known to the skilled artisan. In some embodiments, selectively removing the middle sacrificial layer 240 comprises an etch process that removes the middle sacrificial layer 240 and does not result in material loss in the nanosheet release layers 220. In some embodiments, the etch process comprises one or more of a wet etch process or a dry etch process. In some embodiments, the etch process is a directional etch.

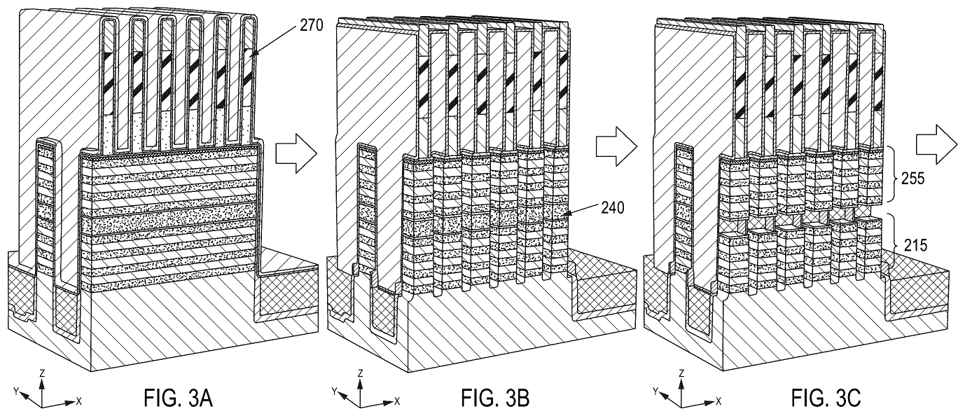

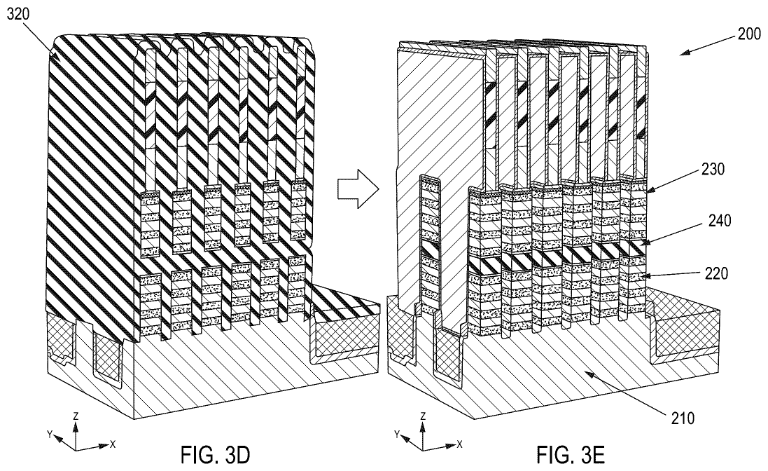

As depicted in FIGS. 3A to 3E, a general process for forming a CFET 200 is depicted in which a vertically stacked superlattice structure 260 is provided comprising a first or lower hGAA 215 on a substrate 210, a middle sacrificial layer 240 disposed on the lower hGAA 215, and a second or upper hGAA 255 stacked on top of the middle sacrificial layer 240, with a gate structure 270 on a top surface of the second or upper hGAA 255, and with a spacer layer 280 deposited on outer surfaces of the gate structure 270. A series of trenches 290 are etched in the vertically stacked superlattice structure 260 to a top surface 212 of the substrate, and source/drain regions are formed. Next, the middle sacrificial layer 240 is selectively removed, for example through an etch process. A middle dielectric isolation (MDI) material is then deposited over the entire structure and fills the cavity left by the removed middle sacrificial layer 240. Finally, the MDI material is removed so that it only remains within the cavity left by the removed middle sacrificial layer 240, thus forming the middle dielectric isolation (MDI) layer 340.

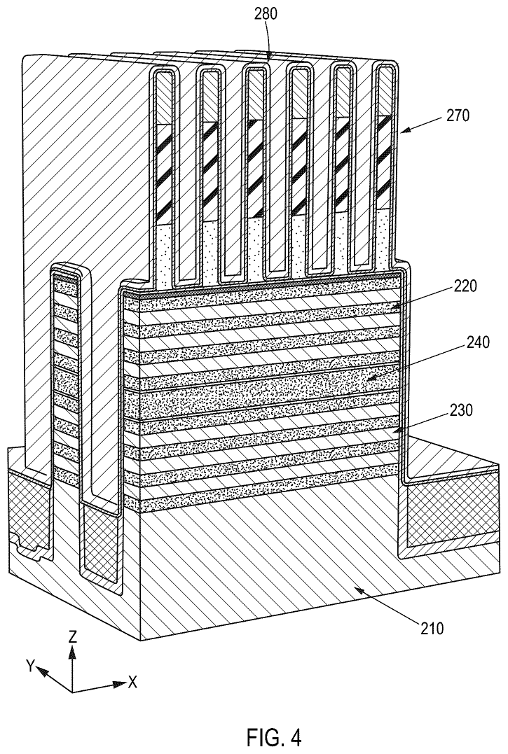

FIG. 4 depicts an enlarged view of an embodiment of the vertically stacked superlattice structure 260 after a spacer layer 280 deposition, corresponding to FIG. 3A. As shown, the first or lower hGAA 215 and the second or upper hGAA 255 each comprise alternating layers of nanosheet channel layer 230 and nanosheet release layer 220. In this embodiment, each nanosheet channel layer 230 comprises silicon (Si), and each nanosheet release layer 230 comprises silicon germanium (SiGe). The middle sacrificial layer 240 comprises silicon germanium (SiGe). As depicted in the embodiment shown by FIGS. 3A-3E and FIG. 4, to selectively remove the middle sacrificial layer 240 while maintaining the nanosheet release layers 220, the middle sacrificial layer 240 is fabricated of silicon germanium (SiGe) having a germanium content that is relatively higher than the germanium content in the nanosheet release layers 220.

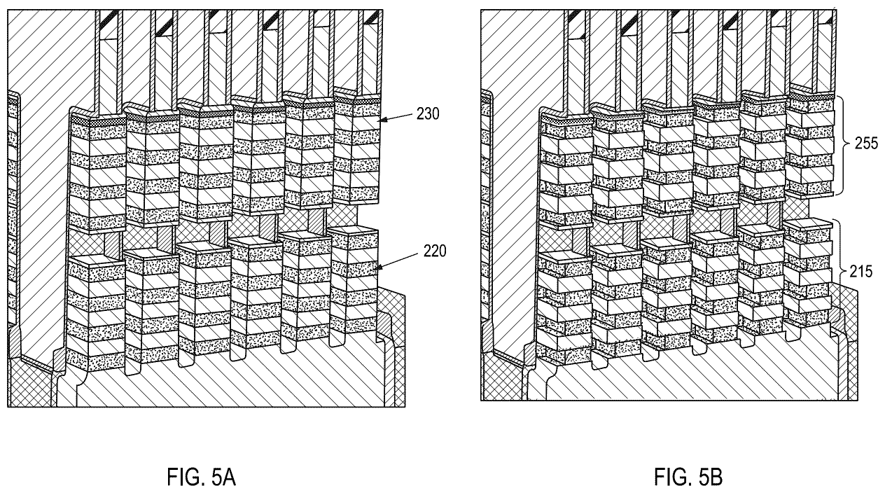

As shown in FIG. 5A, a desired superlattice profile after selective removal of a middle sacrificial layer 240 is smooth and uniform. As depicted, the surfaces of the alternating layers of nanosheet channel layer 230 and nanosheet release layer 220 are even and flush along the stack, with surfaces free from defects. However, it has been discovered that selective removal based on a relatively high germanium content within a middle sacrificial layer 240 results in undesirable material loss in one or more additional layers of material. For example, as shown in FIG. 5B, selective etching of a middle sacrificial layer 240 having a relatively high germanium content compared to the nanosheet release layers 220 results in a material loss from the nanosheet release layers 220. Rather than providing the desired smooth and uniform superlattice profile through selective removal of only the middle sacrificial layer 240, portions of the nanosheet release layers 220 are also removed. As a result, a superlattice profile of alternating nanosheet channel layer 230 and nanosheet release layer 220 is provided in which the outer surfaces of nanosheet release layers 220 are recessed, dip inward, and/or otherwise have a surface roughness due to removed portions of material. As a result, after selective removal of the middle sacrificial layer 240, the nanosheet release layers 220 are otherwise not flush with the outer surfaces of the nanosheet channel layers 230. This loss of material from the nanosheet release layers 220 negatively impacts a subsequent removal process of the nanosheet release layers 220. For example, material loss from the nanosheet release layers 220 results in rough and non-uniform surfaces of nanosheet release layers 220. This can lead to random and non-uniform spacer cavity between the nanosheet channel layers 230, which can cause variation of Vt control. In addition, it has been discovered that material loss also occurs in the nanosheet channel layers 220 (i.e., loss of Si), which produces a smaller (relative to a size of the nanosheet channel layers 230 prior to selective etching of the middle sacrificial layer 240) and rounded shape, as shown in FIG. 5B. This material loss in the nanosheet channel layers 230 negatively impacts source/drain growth and device performance.

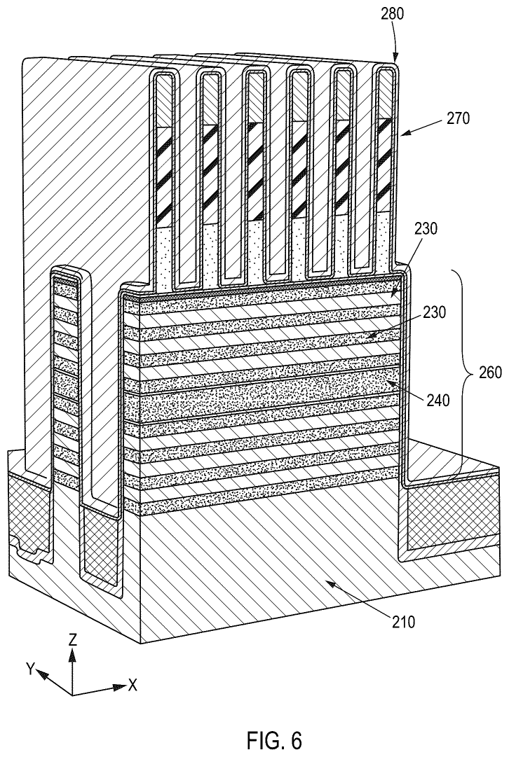

Referring to FIGS. 6-17, according to one or more embodiments, a CFET is provided having a vertically stacked superlattice structure 260 with a smooth profile along upper and lower stacked hGAA structures 215, 255 after removal of a middle sacrificial layer 240, and in which nanosheet channel layers 230 are separated from each other by uniform spacer cavity after subsequent removal of the nanosheet release layers 220. According to one or more embodiments, a CFET and methods of manufacturing such devices are provided wherein nanosheet release layers 220 and channel layers 230 are protected from damage and material loss during removal of a middle sacrificial layer 240. Further, according to one or more embodiments, removal of the middle sacrificial layer 240 without material loss in either the nanosheet channel layers 230 or nanosheet release layers 220 is achieved regardless of the materials used in forming the middle sacrificial layer 240, nanosheet channel layers 230, and nanosheet release layers 220.

As shown in FIG. 6, according to one or more embodiments, a vertically stacked superlattice structure 260 is provided on a substrate 210. The vertically stacked superlattice structure 260 comprises a first or lower horizontal hGAA structure 215 on the substrate top surface 212, a middle sacrificial layer 240 disposed on a top surface 225 of the first or lower hGAA structure 215, and a second or upper hGAA structure 255 disposed on a top surface 245 of the sacrificial layer 240. According to one or more embodiments, the first or lower hGAA structure 215 and the second or upper hGAA structure 255 each individually comprise alternating layers of nanosheet channel layer 230 and nanosheet release layer 220. A gate structure 270 is disposed on a top surface of the second or upper hGAA structure 255. Further, a spacer layer 280 is deposited on outer surfaces of the gate structure 270 and exposed top surfaces of the second or upper hGAA structure 255 (i.e. surfaces not covered by the gate structure 270). It is noted that while six gates are depicted in the embodiment shown in FIGS. 6-17, the methods and structures are not limited to this number.

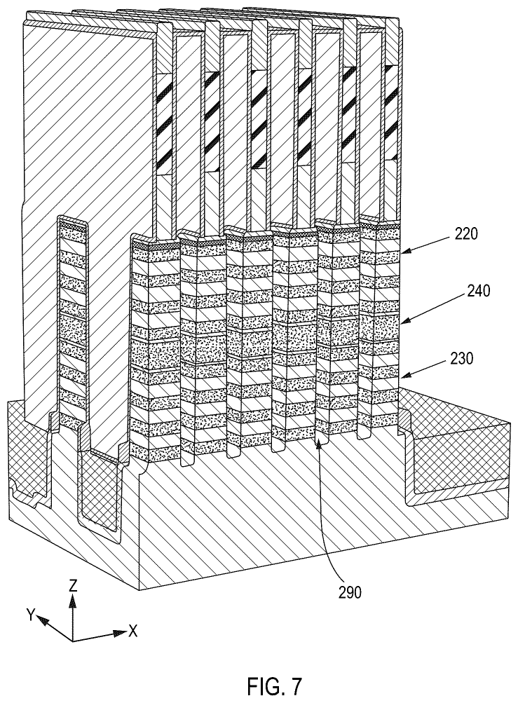

According to one or more embodiments, a series of vertical trenches 290 are etched in the vertically stacked superlattice structure 260 along sides of the gate structure 270. The trenches extend through the second or upper hGAA structure 255, the middle sacrificial layer 240, and first or lower hGAA structure 215, stopping at the substrate top surface 212. Source/drain regions are further formed. The resulting structure is shown in FIG. 7.

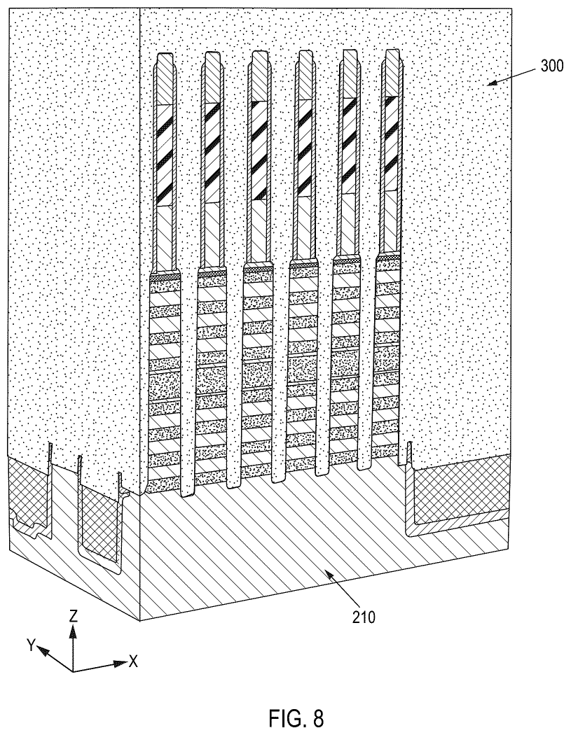

As shown in FIG. 8, a material deposition process followed by planarization has been carried out. According to one or more embodiments, an encapsulating material 300 is deposited to surround the structure (e.g., the structure shown in FIG. 7). The encapsulating material is any suitable material capable of protecting the underlying first or lower hGAA structure 255 during subsequent removal (e.g., by etching or other suitable removal process) of the middle sacrificial layer 240. According to one or more embodiments, the encapsulating material 300 comprises carbon. As shown, according to one or more embodiments the encapsulating material 300 is deposited to fill voids in the entire vertical superlattice structure, including trenches 290, and to surround the vertically stacked superlattice structure 260 and gate structure 270, from the substrate top surface 212 to the tops of the gate structure 270. The encapsulating material 300 can be deposited by using a spin-on, CVD carbon gap-fill, or other suitable process.

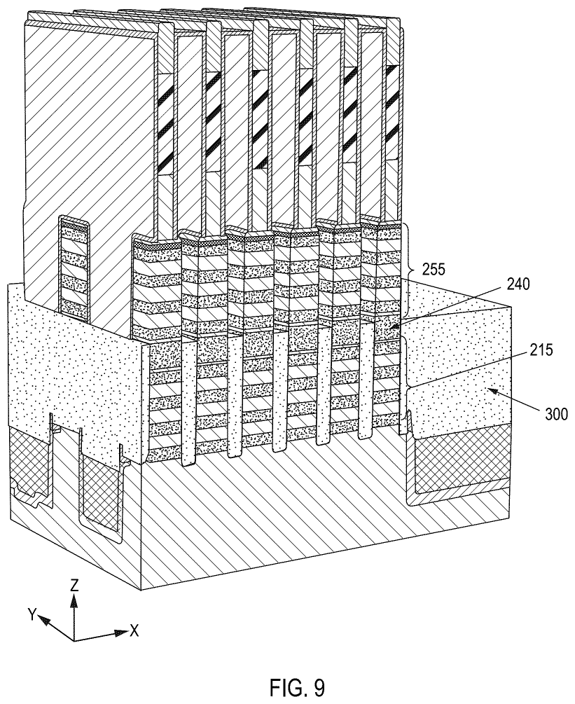

According to one or more embodiments, a portion of the encapsulating material 300 is removed, for example by etching, as shown in FIG. 9. As depicted, the encapsulating material 300 has been removed from around the gate structure 270 and the second or upper hGAA structure 255. As a result, only the substrate 210, first or lower hGAA structure 215, and middle sacrificial layer 240 remain surrounded by the encapsulating material 300, as depicted by FIG. 9.

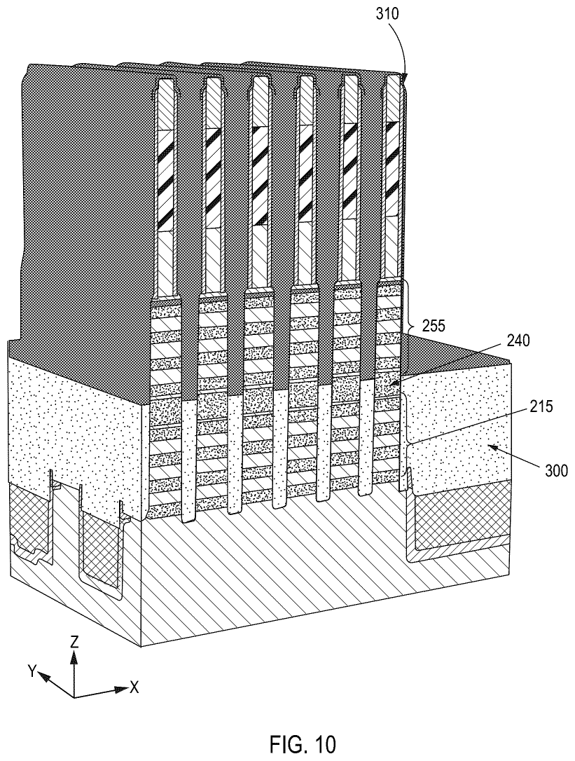

FIG. 10 shows a protection liner 310 deposited on the gate structure 270, the second or upper hGAA structure 255, and exposed top surfaces of the encapsulating material 300 according to one or more embodiments. The protection liner 310 can be formed of any suitable material capable of protecting the underlying upper or second hGAA structure 255 during subsequent removal (e.g., by etching or other suitable removal process) of the middle sacrificial layer 240. According to one or more embodiments, the protection liner 310 comprises a layer of AlOx or SiN having a thickness of at least about 0.5 nm and up to about 4 nm, including a range of from about 0.6 nm to about 3.9 nm, about 0.7 nm to about 3.8 nm, about 0.8 nm to about 3.7 nm, about 0.9 nm to about 3.6 nm, and about 1 nm to about 3.5 nm. In specific embodiments, the protection liner 310 comprises a layer of AlOx or SiN having a thickness in a range of from about 1 nm to about 3 nm, including 1 nm, 1.1 nm, 1.2 nm, 1.3 nm, 1.4 nm, 1.5 nm, 1.6 nm, 1.7 nm, 1.8 nm, 1.9 nm, 2 nm, 2.1 nm, 2.2 nm, 2.3 nm, 2.4 nm, 2.5 nm, 2.6 nm, 2.7 nm, 2.8 nm, 2.9 nm, and 3 nm.

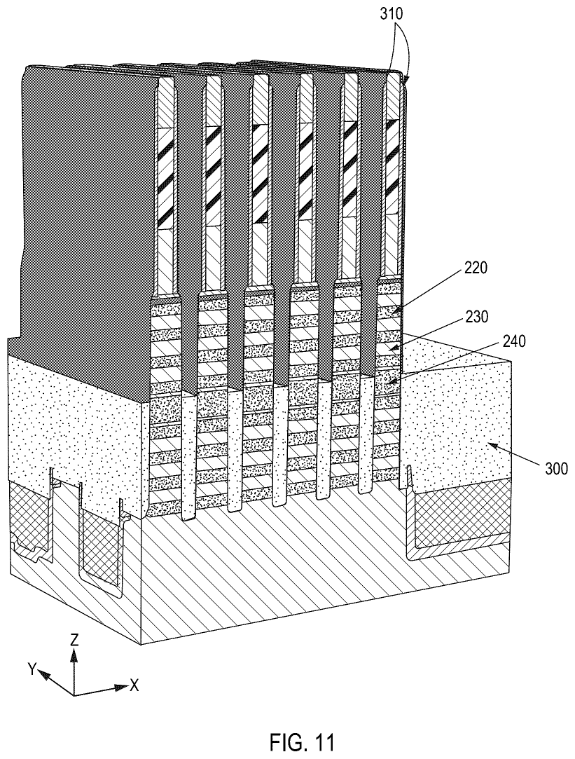

After deposition of the protection liner 310, a bottom open etch process is carried out to remove the protection liner 310 from top surfaces of the encapsulating material 300. As shown in FIG. 11, according to one or more embodiments, the bottom open etch process exposes the top surfaces of the encapsulating material 300 which is disposed on sides of and within trenches 290 of the vertically stacked superlattice structure 260 above the middle sacrificial layer top surface 245.

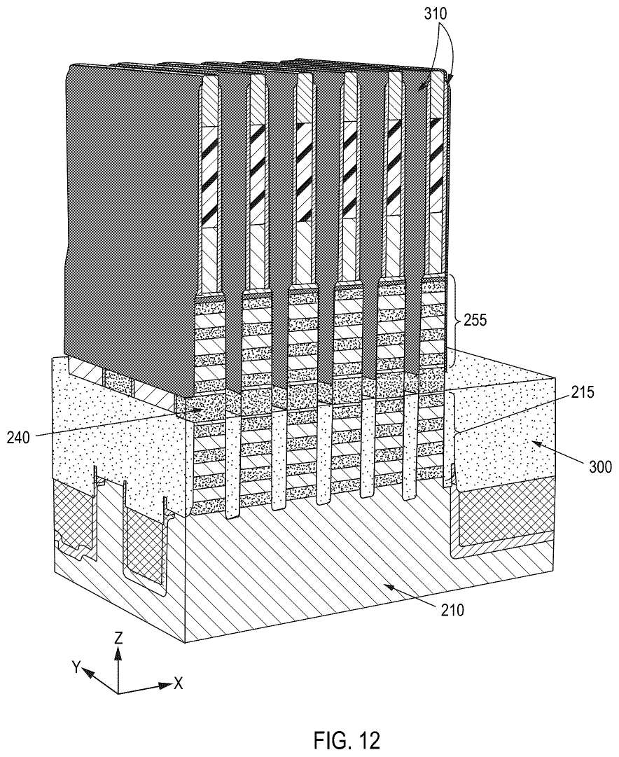

A portion of the encapsulating material 300 is then removed to expose the middle sacrificial layer 240, as depicted in FIG. 12. According to one or more embodiments, a carbon pull back etch is carried out to reveal the middle sacrificial layer 240. As depicted in FIG. 12, a vertically stacked superlattice structure 260 is now provided in which (a) the substrate 210 and first or lower hGAA structure 215 are completely surrounded by and protected by the encapsulating material 300, (b) the gate structure 270 and second or upper hGAA structure 255 are surrounded by and protected by the protection liner 310, and (c) the middle sacrificial layer 240 is exposed for a subsequent etching or removal process.

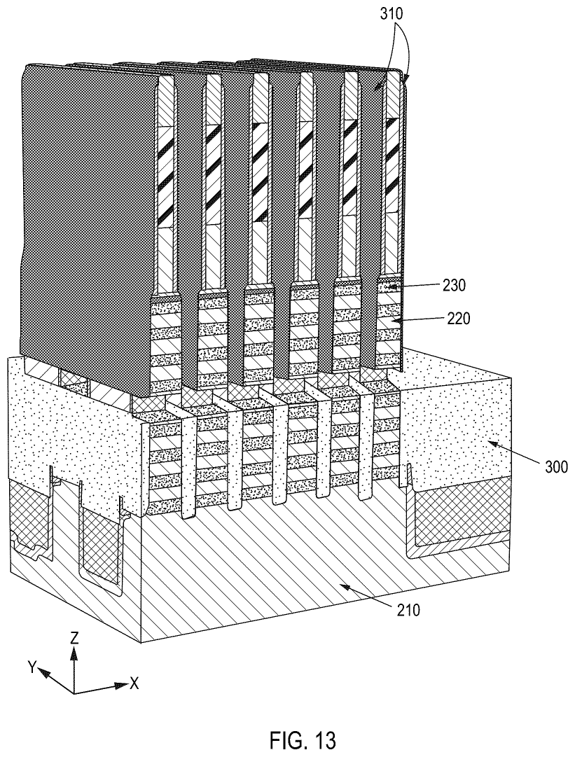

As shown in FIG. 13, the middle sacrificial layer 240 has been removed using an etching or other suitable process, according to one or more embodiments. As the middle sacrificial layer 240 is removed, the substrate 210, first or lower hGAA structure 215, gate structure 270, and second or upper hGAA structure 255 are protected from the removal process (e.g., etching) and material loss.

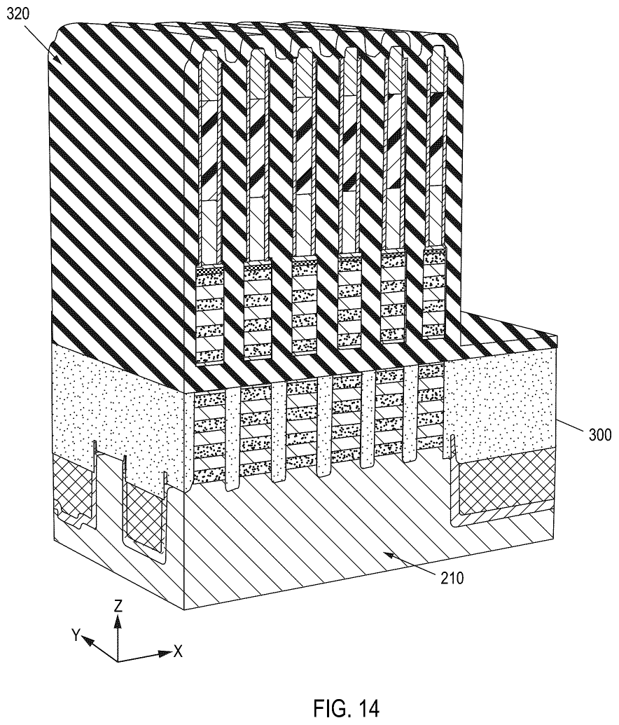

In FIG. 14, a middle dielectric isolation (MDI) material 320 is deposited over the entire structure to fill the cavity left by the removed middle sacrificial layer 240, trenches 290, and to cover an outer surface of the device from the encapsulating material 300 upwards. Advantageously, deposition of the MDI material 320 while the encapsulating material 300 covers the first or lower hGAA structure 215 provides a lower aspect ratio, which facilitates the deposition process.

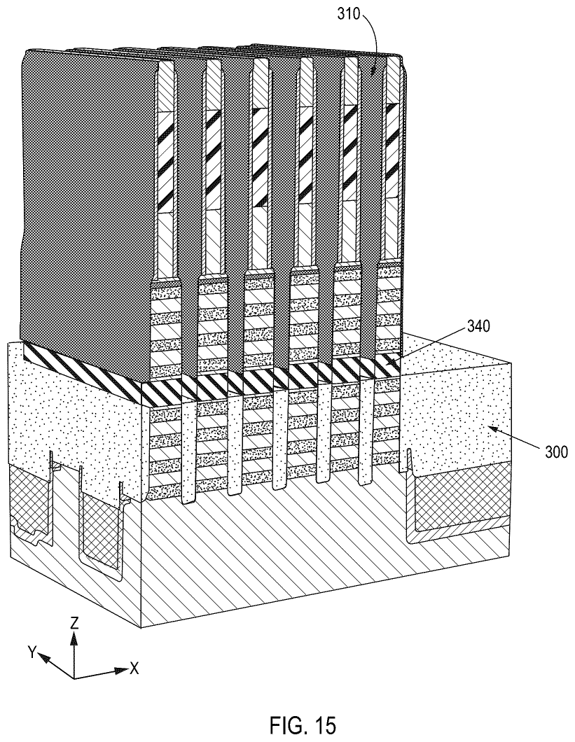

According to one or more embodiments as shown in FIG. 15, the MDI material 320 is trimmed back so that it remains only within the cavity left by the removed middle sacrificial layer 240. The trim back process is, likewise, facilitated by the reduced aspect ratio provided by the encapsulating material 300. Densification of the MDI material 320 is then carried out to form the middle dielectric isolation (MDI) layer 340.

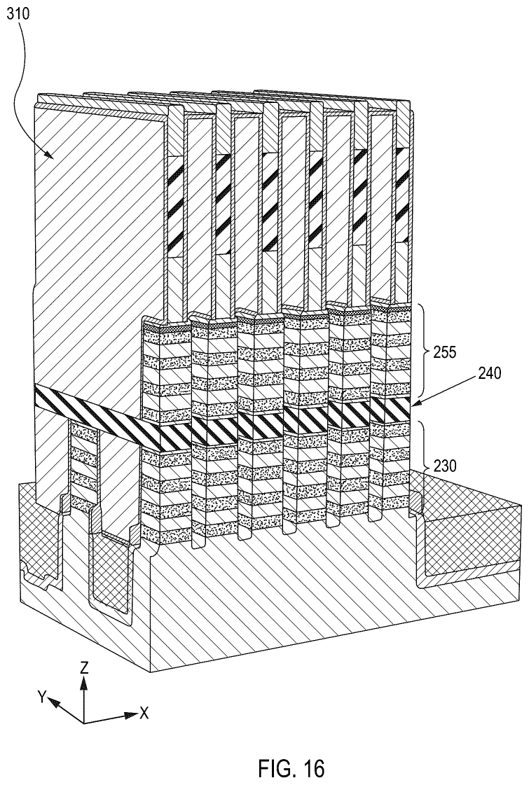

As shown in FIG. 16, according to one or more embodiments, the remainder of the encapsulating material 300 is removed. For example, in embodiments wherein the encapsulating material 300 is carbon, a radical ash can be carried out to remove the carbon material and expose the first or lower hGAA structure 215.

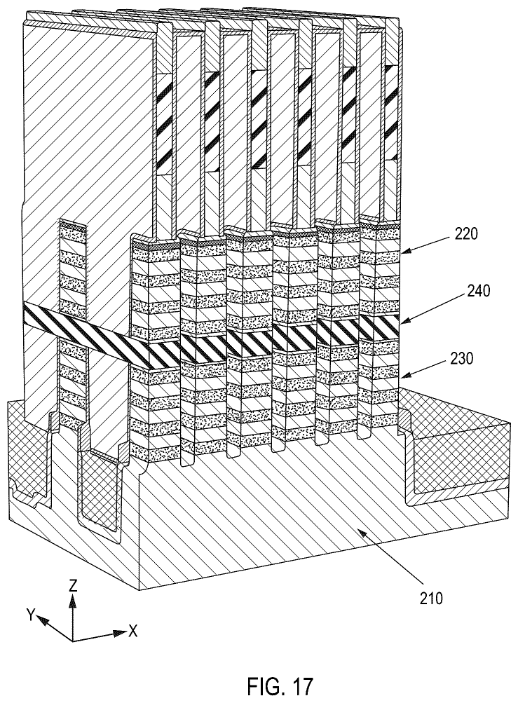

In FIG. 17, the protection liner 310 is removed to expose the gate structure 270 and the second or upper hGAA structure 255.

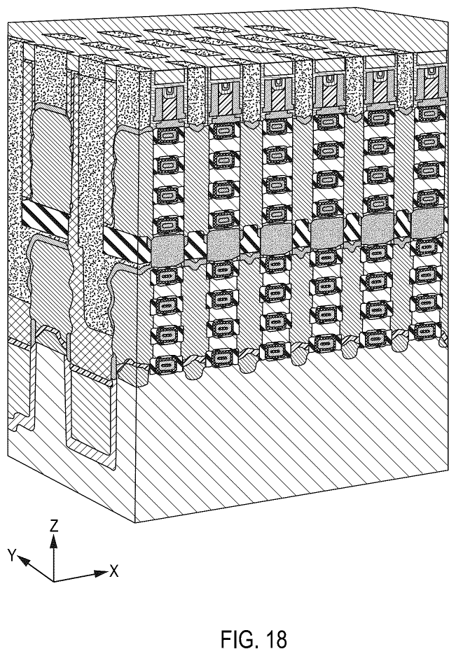

With the first and second hGAA structures 215, 255 now exposed, further processing steps can be carried out, including a selective etching process to remove the nanosheet release layers 220 and form uniform cavities separating the nanosheet channel layers 230. A CFET formed according to one or more embodiments after further processing steps is shown, for example, in FIG. 18.

According to one or more embodiments, methods and structures are provided for forming electronic devices, particularly CFETs, in which shallow trench isolation (STI) oxide loss is reduced or prevented. In particular, during typical etching and cleaning procedures, STI loss is induced, which can result in an Si fin base becoming completely exposed. Subsequent epitaxial growth of the source/drain can result in growth from the bottom Si fin sidewall, which can induce electrical failures. Without being bound by theory, according to one or more embodiments, the encapsulating material 300 provides a shield for the underlying components from cleaning, removal, and etching steps throughout the fabrication process, including during etching of the middle sacrificial layer 240 and MDI layer 340 trim back. Providing the encapsulating material 300 according to one or more embodiments shields the underlying components and, thus, reduces or even prevents STI loss.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor device, the method comprising:
forming a vertically stacked superlattice structure on a substrate by
forming a first horizontal gate-all-around (hGAA) structure on the substrate, the first hGAA structure comprising alternating layers of nanosheet channel layer and nanosheet release layer;
forming a middle sacrificial layer on a top surface of the first hGAA structure;
forming a second horizontal gate-all-around (hGAA) structure on a top surface of the middle sacrificial layer, the second hGAA structure comprising alternating layers of nanosheet channel layer and nanosheet release layer;
depositing an encapsulating material to fill one or more trenches in the vertically stacked superlattice structure and surround the vertically stacked superlattice structure;
removing a portion of the encapsulating material to expose the second hGAA structure;
depositing a protection liner on the second hGAA structure;
removing a portion of the encapsulating material to expose the middle sacrificial layer; and
removing the middle sacrificial layer,
wherein the first hGAA structure is covered by the encapsulating material and the second hGAA structure is covered by the protective liner during removal of the middle sacrificial layer.

2. The method of claim 1, wherein depositing the encapsulating material to fill one or more trenches in the vertically stacked superlattice structure and surround the vertically stacked superlattice structure comprises performing a spin-on or chemical vapor deposition (CVD) carbon gap-fill process.

3. The method of claim 1, wherein the protection liner comprises a layer of AIOx or SiN.

4. The method of claim 3, wherein depositing the protective liner comprises depositing a layer of AlOx or SiN having a thickness ranging from about 0.5 nm to about 4 nm.

5. The method of claim 1, wherein removing the middle sacrificial layer comprises etching the middle sacrificial layer.

6. The method of claim 5, wherein the encapsulating material and the protective liner shield the first hGAA structure and the second hGAA structure and prevents material loss in the alternating layers of nanosheet release layer and nanosheet channel layer during etching.

7. The method of claim 1, further comprising, after removing the middle sacrificial layer, depositing a middle dielectric isolation (MDI) material within at least a cavity formed by removing the middle sacrificial layer, removing an excess of deposited MDI material so that MDI material remains only within the cavity, and densifying the MDI material to form a MDI layer.

8. The method of claim 7, further comprising, after densifying the MDI material, removing the encapsulating material and the protective liner to expose the first hGAA structure and the second hGAA structure, and performing a selective etch to remove the alternating layers of nanosheet release layer from the first hGAA structure and the second hGAA structure.

9. The method of claim 1, wherein the alternating layers of nanosheet channel layer comprise silicon (Si), the alternating layers of nanosheet release layer comprise silicon germanium (SiGe), and the middle sacrificial layer comprises silicon germanium (SiGe).

10. The method of claim 9, wherein the alternating layers of nanosheet release layer comprise silicon germanium (SiGe) having a germanium content of from about 10% to about 40% on an atomic basis, and the middle sacrificial layer comprises silicon germanium (SiGe) having a germanium content of from about 10% to about 65% on an atomic basis.

11. The method of claim 10, wherein the alternating layers of nanosheet release layer comprise silicon germanium (SiGe) having a germanium content of from about 15% to about 35% on an atomic basis, and the middle sacrificial layer comprises silicon germanium (SiGe) having a germanium content of from about 15% to about 35% on an atomic basis.

12. The method of claim 9, wherein the alternating layers of nanosheet release layer and the middle sacrificial layer are fabricated of the same material.

13. The method of claim 1, wherein an etch selectivity of a material forming the alternating layers of nanosheet release layer is the same as an etch selectivity of a material forming the middle sacrificial layer.

14. The method of claim 7, wherein depositing the MDI material and removing the excess of deposited MDI material while the first hGAA structure is covered by the encapsulating material provides a lower aspect ratio for depositing and removing the MDI material.

15. The method of claim 7, wherein densifying the MDI material while the first hGAA structure is covered by the encapsulating material and while the second hGAA structure is covered by the protective liner facilitates densification of the MDI material.

16. A method of forming a semiconductor device, the method comprising:
forming a vertically stacked superlattice structure on a substrate by
forming a first horizontal gate-all-around (hGAA) structure on the substrate, the first hGAA structure comprising alternating layers of nanosheet channel layer and nanosheet release layer;
forming a middle sacrificial layer on a top surface of the first hGAA structure;
forming a second horizontal gate-all-around (hGAA) structure on a top surface of the sacrificial layer, the second hGAA structure comprising alternating layers of nanosheet channel layer and nanosheet release layer; and
etching the middle sacrificial layer,
wherein the alternating layers of nanosheet release layer in the first hGAA structure and the second hGAA structure and the middle sacrificial layer comprise the same material,
wherein the second hGAA structure is shielded by a protective liner while etching the middle sacrificial layer and the first hGAA structure is shielded by an encapsulating material while etching the middle sacrificial layer, and
wherein etching the middle sacrificial layer results in no material loss in the alternating layers of nanosheet release layer in the first hGAA structure and the second hGAA structure.

17. The method of claim 16, wherein the encapsulating material is carbon and is deposited on the first hGAA structure using a spin-on or chemical vapor deposition (CVD) carbon gap-fill process.

18. The method of claim 16, wherein the protection liner comprises a layer of AIOx or SiN.

19. The method of claim 16, wherein the alternating layers of nanosheet channel layer comprises silicon (Si), the alternating layers of nanosheet release layer comprise silicon germanium (SiGe), and the middle sacrificial layer comprises silicon germanium (SiGe).

20. The method of claim 19, wherein the alternating layers of nanosheet release layer and the middle sacrificial layer individually comprise silicon germanium (SiGe) having the same germanium content.
